(19) United States
(12) Patent Application Publication
(10) Pub. No.: US 2005/0221868 A1
(43) Pub. Date: Oct. 6, 2005

(54) Method and apparatus for volume reduction in a vehicle

(75) Inventors: Rhonda L. Childress, Austin, TX (US); David Bruce Kumhyr, Austin, TX (US); Neil Raymond Pennell, Cedar Creek, TX (US)

Correspondence Address: IBM CORP (YA);C/O YEE & ASSOCIATES PC, P.O. BOX 802333, DALLAS, TX, 75380, US

(73) Assignee: International Business Machines Corporation, Armonk, NY (US)

(21) Appl. No.: 10/809,585

(22) Filed: Mar. 25, 2004

(51) Int. Cl. H03G 3/00; H04B 1/00; H04M 1/00

(52) U.S. Cl. 455/569.2

(57) ABSTRACT

A method, apparatus, and computer instructions for managing an audio system volume in a vehicle. A radio frequency transmission having a selected frequency is detected through a sensor coupled to the audio system. The selected frequency for this transmission is typically used by a mobile telecommunications device within the vehicle. The audio system volume is reduced in response to detecting the radio frequency transmission, until an absence of the radio frequency transmission occurs. When the radio frequency transmission terminates, the audio system volume is changed, typically to the level present prior to the radio frequency transmission being detected.

### BACKGROUND OF THE INVENTION

1. Technical Field

The present invention relates generally to an improved data processing system. Still more particularly, the present invention provides a method, apparatus, and computer instructions for managing the volume of a radio in a vehicle.

2. Description of Related Art

The devices in vehicles have become increasingly complex. Vehicles may include computers or processors that provide a variety of functions. For example, a vehicle may include a navigation system to provide directions, as well as the current position of the vehicle. Diagnostic and warning systems are also present to tell a user when a vehicle needs service or when a condition requiring attention arises. These vehicles also include integrated wireless communications systems, such as cellular phones.

Current systems allow for the volume of a radio to be increased or decreased under different situations. For example, the volume of a radio may be increased as the speed of the vehicle increases to take into account the presence of increased road noise. Further, some vehicles with phones integrated into the car are able to reduce the volume of a radio when a call is received or made using a cellular phone. This ability comes from the system being able to identify when a call is being received or made. This ability comes from the phone being integrated with the rest of the electronic devices in the vehicle.

In the case of a mobile phone user, such a volume reduction feature is unavailable. When a mobile phone is not electrically connected to the vehicle, the computing system in the vehicle is unaware of the mobile phone. With this situation, an incoming call currently cannot be detected by the computing system and the radio volume cannot be decreased so that the user is able to hear the ring tone for the mobile phone. Currently, the user must play the radio at a lower volume and, when a call is received, must manually decrease the volume. When the call is completed, the user must then manually return the volume to the desired level, prior to receiving the call. These steps are tedious and potentially dangerous for a mobile phone user. Additionally, the user may miss a call in some cases because the user is unable to hear the ring tone indicating that a call is present.

Therefore, it would be advantageous to have an improved method, apparatus, and computer instructions for managing the volume of a radio when a user is receiving a call in a vehicle.

### SUMMARY OF THE INVENTION

The present invention provides a method, apparatus, and computer instructions for managing an audio system volume in a vehicle. A radio frequency transmission having a selected frequency is detected through a sensor coupled to the audio system. The selected frequency for this transmission is typically used by a mobile telecommunications device within the vehicle. The audio system volume is reduced in response to detecting the radio frequency transmission, until an absence of the radio frequency transmission occurs. When the radio frequency transmission terminates, the audio system volume is changed, typically to the level present prior to the radio frequency transmission being detected.

### BRIEF DESCRIPTION OF THE DRAWINGS

The novel features believed characteristic of the invention are set forth in the appended claims. The invention itself, however, as well as a preferred mode of use, further objectives and advantages thereof, will best be understood by reference to the following detailed description of an illustrative embodiment when read in conjunction with the accompanying drawings, wherein:

FIG. 1 is a block diagram of an automotive computing platform in accordance with a preferred embodiment of the present invention;

FIG. 2 is a diagram illustrating components used in managing the volume of a radio unit in a vehicle in accordance with a preferred embodiment of the present invention; and

FIG. 3 is a flowchart of a process for managing the volume of an audio system in accordance with a preferred embodiment of the present invention.

### DETAILED DESCRIPTION OF THE PREFERRED EMBODIMENT

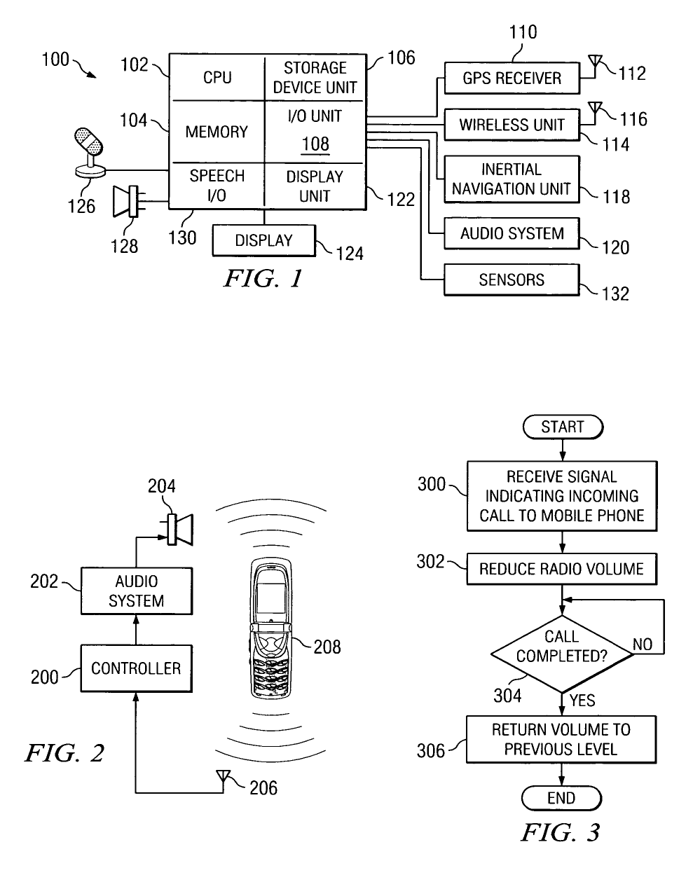

With reference now to the figures, and with reference to FIG. 1, a block diagram of an automotive computing platform is depicted in accordance with a preferred embodiment of the present invention. Computing platform 100 is located within a vehicle, such as an automobile or a truck. Computing platform 100 includes CPU 102, which may be an embedded processor or a processor, such as a Pentium processor from Intel Corporation. “Pentium” is a trademark of Intel Corporation. Computing platform 100 also includes memory 104 which may take the form of random access memory (RAM) and/or read-only memory (ROM).

Computing platform 100 also contains storage device unit 106. Storage device unit 106 may contain one or more storage devices, such as, for example, a hard disk drive, a flash memory, a DVD drive, or a floppy disk. Computing platform 100 also includes input/output (I/O) unit 108, which provides connections to various I/O devices. In this example, a GPS receiver, such as GPS receiver 110, is included within computing platform 100 and receives signals through antenna 112.

Wireless unit 114 provides for two-way communications between computing platform 100 and another data processing system. This communication may be established using TCP/IP protocols normally found on the Internet. Communications are provided through antenna 116. These communications may take various forms, such as, RF signals, Wi-Fi, and Bluetooth.

In addition, inertial navigation unit 118 is connected to I/O unit 108. Inertial navigation unit 118 is employed for navigation when GPS receiver 110 is unable to receive a usable signal or is inoperable.

Audio system 120 also is connected to I/O unit 108. Audio system 120 includes a radio that may be tuned to various radio stations via different mediums. Audio system 120 also may include other components, such as a CD-ROM player or an MP3 device. Audio system 120 may receive broadcasts from a variety of mechanisms. For example, audio system 120 may receive broadcasts via traditional airway broadcasts, such as AM or FM broadcasts, or satellite radio broadcasts. These traditional airway broadcasts are typically analog broadcasts, while the satellite radio broadcasts are digital ones. Also, audio system 120 may receive Internet broadcasts by tuning or connecting to IP addresses for desired radio stations. Internet connections may be established using any wireless connection system for Internet access. In these examples, dynamic tuning in audio system 120 may be controlled through CPU 102.

Computing platform 100 also includes display unit 122, which is connected to display 124. In the depicted example, this display is a touch screen display. Alternatively or in addition to a touch screen display, display 124 also may employ a heads-up display projected onto the windshield of the automobile. Computing platform 100 also includes microphone 126 and speaker 128 to provide a driver with the ability to enter commands and receive responses through speech I/O 130 without having to divert the driver's attention away from the road, or without the driver having to remove the driver's hands from the steering wheel.

Additionally, computing platform 100 also includes sensors 132. These sensors include various devices, such as an accelerometer and a temperature sensor. In these examples, sensors 132 include a radio frequency sensor in the form of an antenna that is designed to detect radio frequency signals used by wireless communication devices, such as a mobile phone.

The present invention provides a method, apparatus, and computer instructions for managing the volume of an audio system, such as a radio or car stereo. This volume also is referred to as an audio system volume. When an incoming call occurs, a sensor, such as an antenna, is used to detect radio frequencies transmitted by a mobile phone within the vehicle. When this radio frequency is detected, the audio system volume is reduced. The reduction of the volume allows a user to hear the ring tone for the mobile phone. The volume remains at the reduced level until the end of the call. When the call terminates, the radio frequency emitted by the mobile phone is no longer detected by the sensor. At this time, the volume may be changed to its previous setting prior to detecting the radio frequency emitted by the mobile phone. In these examples, computer instructions may be included for execution by CPU 102 to provide for controlling the volume of the audio system when calls are detected for the mobile phone.

With reference now to FIG. 2, a diagram illustrating components used in managing the volume of a radio unit in a vehicle is depicted in accordance with a preferred embodiment of the present invention. In this example, controller 200, audio system 202, and speaker 204 are components located in a vehicle. These components may be part of a computing platform, such as computing platform 100 in FIG. 1. Controller 200 may take the form of a processor, such as CPU 102 in FIG. 1. Audio system 202 may play music, which is presented through speaker 204. Controller 200 is connected to a sensor in the form of antenna 206.

Antenna 206 is designed to receive radio frequency transmissions from communications devices such as mobile phone 208. In this example, mobile phone 208 is a global system for mobile communications (GSM) phone. In this example, mobile phone 208 may operate using frequencies in the area of 900 MHz, 1800 MHz, and 1900 MHz. Antenna 206 is designed to detect these frequencies and provide an indication of the receipt of these frequencies to controller 200.

In response to detecting radio frequency transmissions by mobile phone 208, controller 200 sends a signal or command to reduce the volume for audio system 202. The transmissions by mobile phone 208 may begin when mobile phone 208 acknowledges its presence to the GSM system that an incoming call is present. This transmission by mobile phone 208 continues if the call is answered and terminates when the call ends. When these transmissions are no longer detected by antenna 206, controller 200 will return the volume of audio system 202 to its prior setting. In reducing the volume, the volume may be reduced to some default or preselected level. The preselected level may be one set by the user of the system. Additionally, the reduction of the volume may be to an off or zero decibel level. These default and preset settings, as well as other settings, may be stored in a memory or storage device associated with controller 200, such as memory 104 in FIG. 1.

In detecting radio frequency transmissions, controller 200 may require the transmission level to reach or exceed some strength level. In these examples, the level or strength of the radio frequency signal detected by antenna 206 is one present for a mobile phone that is located within the vehicle. This threshold is selected to be high enough to avoid reducing the audio system volume when mobile phones outside of the vehicle are being used. Additionally, selected frequencies may be required to reduce the volume. For example, the up link frequency in a 900 MHz GSM system is typically about 890 MHz to about 915 MHz. This is the frequency range that the mobile phone transmits to the base transceiver station. The base station typically transmits to the phone in the downlink using a frequency of about 935 MHz to about 960 MHz. These frequencies vary a bit from cell to cell to avoid interference between cells in the overall cellular network. As a result, in a preferred embodiment, controller 200 may reduce the audio volume when transmission frequencies are detected in the range from about 890 MHz to about 915 MHz having a signal strength greater than some selected threshold indicating the phone is in use. Alternatively, the antenna may be shaped or configured so that signals inside the vehicle are detected preferentially over those originating from outside the vehicle.

Alternatively, controller 200 may be configured to identify messages being sent to and from mobile phone 208 to identify when a call is being initiated or set up and when a call terminates. For example, in a call to mobile phone 208, various messages are sent to this device to indicate that an incoming call is present. For example, the paging message or request may be received to indicate an incoming call. This message may be used to determine that an incoming call is present. When mobile phone 208 completes the call, a call disconnect message may be sent to indicate that the call is being terminated. The particular types of messages identified and used may vary depending on the wireless system. Controller 200, in this type of illustrative embodiment, is configured to recognize the types of messages in determining whether an incoming call is present or when a call has terminated.

With reference now to FIG. 3, a flowchart of a process for managing the volume of an audio system is depicted in accordance with a preferred embodiment of the present invention. The process illustrated in FIG. 3 may be implemented in a computing platform, such as computing platform 100 in FIG. 1.

The process begins by receiving a signal indicating an incoming call to a mobile phone (step 300). Step 300 may be implemented by filtering out radio frequency signals and strengths that are not characteristic of a mobile phone located in a vehicle as described above. Next, the radio volume is reduced (step 302). In reducing the volume in step 302, a preset volume may be retrieved with the radio volume being reduced to that preset volume. Then, a determination is made as to whether the call is completed (step 304). This determination in step 304 may be made by identifying whether the radio frequency transmission from the mobile phone has terminated. Step 304 may be implemented using periodic polling to determine whether the signal for the radio frequency transmission is still present. Depending on the wireless system, the call may be identified as completed if the radio frequency transmission terminates without restarting for some selected period of time. This selected time period may be set having intervals between several seconds and one minute in these illustrative embodiments. This selected period of time may be user configurable.

If the call is completed, volume is returned to the previous level (step 306) with the process terminating thereafter. Referring back to step 304, if the call is not completed, then the process returns to step 304.

Thus, the present invention provides an improved method, apparatus, and computer instructions for managing audio system volume in a vehicle. When a radio frequency emitted by a mobile phone is detected, the audio system volume is reduced. This volume remains in the reduced state until the mobile phone ceases emitting the radio frequency transmission, which indicates that the call has ended or the phone has stopped ringing. In this manner, a mobile phone user in a vehicle may more easily hear the ring tone that occurs when an incoming call is present. Further, the user may conduct the call with the radio at a lower volume. The volume is returned to the previous level without the user having to adjust the audio system volume.

It is important to note that while the present invention has been described in the context of a fully functioning data processing system, those of ordinary skill in the art will appreciate that the processes of the present invention are capable of being distributed in the form of a computer readable medium of instructions and a variety of forms and that the present invention applies equally regardless of the particular type of signal bearing media actually used to carry out the distribution. Examples of computer readable media include recordable-type media, such as a floppy disk, a hard disk drive, a RAM, CD-ROMs, DVD-ROMs, and transmission-type media, such as digital and analog communications links, wired or wireless communications links using transmission forms, such as, for example, radio frequency and light wave transmissions. The computer readable media may take the form of coded formats that are decoded for actual use in a particular data processing system.

The description of the present invention has been presented for purposes of illustration and description, and is not intended to be exhaustive or limited to the invention in the form disclosed. Many modifications and variations will be apparent to those of ordinary skill in the art. The embodiment was chosen and described in order to best explain the principles of the invention, the practical application, and to enable others of ordinary skill in the art to understand the invention for various embodiments with various modifications as are suited to the particular use contemplated.

1. A method for managing an audio system volume in a vehicle, the method comprising:
detecting a radio frequency transmission having a selected frequency through a sensor, wherein the selected frequency is indicative of a call for a mobile telecommunications device within the vehicle; and
responsive to detecting the radio frequency transmission, reducing the audio system volume, until an absence of the radio frequency transmission occurs indicating that the call has terminated.

2. The method of claim 1, wherein the mobile telecommunications device is a global system for a mobile communications phone.

3. The method of claim 1, wherein the selected frequency has a range from about 890 MHz to about 960 MHz.

4. The method of claim 1, wherein the audio system volume is reduced to zero decibels.

5. The method of claim 1, wherein the audio system volume is reduced to a preselected volume.

6. The method of claim 1, wherein the sensor is an antenna configured to detect radio frequency signals.

7. The method of claim 1, wherein the vehicle is an automobile.

8. The method of claim 5, wherein the preselected volume is user configurable.

9. A method for managing an audio system volume in a vehicle, the method comprising:
detecting a radio frequency transmission having a selected frequency through a sensor, wherein the selected frequency is indicative of a call for a mobile telecommunications device within the vehicle; and
responsive to detecting the radio frequency transmission, reducing the audio system volume, until another radio frequency transmission occurs indicating that the call has terminated.

10. The method of claim 9, wherein the another radio frequency transmission is a request by the mobile telecommunications device to disconnect the call.

11. The method of claim 9, wherein the radio frequency transmission is a paging message transmitted to the mobile telecommunications device.

12. The method of claim 9, wherein the audio system volume is reduced to a preselected volume.

13. The method of claim 12, wherein the preselected volume is used or configured.

14. An apparatus for controlling an audio system volume, the apparatus comprising:
a radio unit;
a sensor; and
a controller connected to the radio unit and the sensor, wherein the controller sends a signal to the radio unit to reduce volume when an indication is received from the sensor that a radio frequency signal for a mobile phone has been detected and the volume remains reduced until the radio frequency signal is absent indicating that the call has terminated.

15. A data processing system for managing an audio system volume in a vehicle, the data processing system comprising:
detecting means for detecting a radio frequency transmission having a selected frequency through a sensor, wherein the selected frequency is indicative of a call for a mobile telecommunications device within the vehicle; and
reducing means, responsive to detecting the radio frequency transmission, for reducing the audio system volume, until an absence of the radio frequency transmission occurs indicating that the call has terminated.

16. The data processing system of claim 15, wherein the mobile telecommunications device is a global system for a mobile communications phone.

17. The data processing system of claim 15, wherein the selected frequency has a range from about 890 MHz to about 960 MHz.

18. The data processing system of 15, wherein the data processing system is a computing platform for a vehicle.

19. The data processing system of claim 15, wherein the audio system volume is reduced to a preselected volume.

20. The data processing system of claim 19, wherein the preselected volume is used or configured.
